(19) United States
(12) Patent Application Publication
(10) Pub. No.: US 2017/0034924 A1
(43) Pub. Date: Feb. 2, 2017

(54) METHOD FOR FABRICATING DISPLAY PANEL

(71) Applicant: JOLED INC., Tokyo (JP)

(72) Inventor: Kanemitsu NAKAJUN, Osaka (JP)

(73) Assignee: JOLED INC., Tokyo (JP)

(21) Appl. No.: 15/106,854

(22) PCT Filed: Nov. 17, 2014
(86) PCT No.: PCT/JP2014/005762

§ 371 Date: Jun. 21, 2016

(30) Foreign Application Priority Data
Dec. 26, 2013 (JP) 2013-268275

(51) Int. Cl. H05K 3/36; H05K 3/28; B05D 1/02

(52) U.S. Cl. CPC H05K 3/361; B05D 1/02; H05K 3/28; G02F 1/13452

(57) ABSTRACT

Applying a protective resin to a border portion of a substrate includes: moving a nozzle at a speed of 26 mm/s or greater and 28 mm/s or less, if within 144 hours after a container containing the protective resin is first opened; moving the nozzle at a speed of 24 mm/s or greater and less than 26 mm/s, if beyond 144 hours after the container is first opened; dispensing the protective resin pressurized by a gas having a predetermined pressure from the nozzle, when a position of the nozzle relative to a position of the substrate is a first position; and stopping dispensing the protective resin when the position of the nozzle relative to the position of the substrate is a second position.

### TECHNICAL FIELD

The present disclosure relates to a method for fabricating a display panel such as liquid crystal display panels and organic EL display panels.

### BACKGROUND ART

A slim, lightweight display apparatus that includes a display panel, such as a liquid crystal display panel and an organic EL display panel, is known. The display panel has a rectangular display area in which pixels are arranged in a matrix in the center of a rectangular substrate such as a glass plate, and includes electronic components for controlling flashing of the pixels. The electronic components are mounted on the substrate in a location, other than the display area (between the periphery of the display area and the periphery of the substrate), a so-called border portion.

As a specific example, as disclosed in Patent Literature (PTL) 1, a plurality of electrodes are disposed in the border portion on the substrate along the periphery of the substrate, and connected to a plurality of chip-on-films (COF) arranged at a predetermined distance from one another. The chip-on-film (COF) is a flexible printed circuit film having, mounted thereon, electronic components for applying voltage to the pixels. The electrode and the COF are electrically connected and also mechanically affixed to each other by thermocompression bonding via an anisotropic conductive film (ACF).

At the interface of the electrode and the COF which are linearly arrayed, resin is linearly applied over the COF and cured, thereby protecting the interface of the COF and the electrode (substrate).

### CITATION LIST

### Patent Literature

[PTL 1] Japanese Unexamined Patent Application Publication No. 2012-182442

### SUMMARY OF INVENTION

### Technical Problem

To apply the resin for protecting the interface of the COF and the electrode mentioned above, an application apparatus equipped with a syringe may be used. Specifically, the application apparatus dispenses resin from a nozzle at the tip of the syringe while moving the nozzle relative to the substrate along one side of the substrate, thereby applying the resin covering the interface of the substrate and the COF.

In a meanwhile, the application state of the resin depends on the conditions of resin to be loaded into the syringe, for example, depends on resin viscosity differences due to aging. Thus, in order to produce a stable, quality display panel, the set of conditions relying upon guesswork by an operator are necessary. In these days in particular, so-called narrow-border display panels which have narrow border portions have emerged. Accordingly, an amount of resin dispensed is reduced, causing greater changes in resin application state in response to changes in conditions of the resin. This makes it difficult to stabilize the resin application state.

The present disclosure is made in view of the above problem and has objects to provide a method for fabricating a display panel which stabilizes the state of resin applied to a connection between a substrate and a film, and improves a yield rate of display panel production, even if the conditions of the resin have been changed over time.

### Solution to Problem

In order to achieve the above objects, a method for fabricating a display panel according to one aspect of the present disclosure is a method for fabricating a display panel in which a film which includes a conductor is connected to a border portion of a substrate having a rectangular shape, the border portion being between a periphery of the substrate and a periphery of a display area, the method including linearly applying a protective resin to a surface of the border portion onto which the film is connected, the protective resin protecting a connection between the substrate and the film, wherein linearly applying the protective resin includes: loading the protective resin having a viscosity of 4 Pa·s or greater and 6 Pa·s or less in an environment of 23 degrees Celsius into a syringe to which a nozzle is connected, the nozzle having a bore diameter 20% or greater and 30% or less of a width of the border portion; moving one of the substrate and the nozzle at a relative speed between the substrate and the nozzle of 26 mm/s or greater and 28 mm/s or less, if within 144 hours after a container containing the protective resin is first opened; moving one of the substrate and the nozzle at a relative speed between the substrate and the nozzle of 24 mm/s or greater and less than 26 mm/s, if beyond 144 hours after the container containing the protective resin is first opened; dispensing the protective resin pressurized by a gas having a pressure of 200 kPa or greater and 280 kPa or less from the nozzle, when a position of the nozzle relative to a position of the substrate is a first position; and stopping dispensing the protective resin when the position of the nozzle relative to the position of the substrate is a second position.

### Advantageous Effects of Invention

According to the present disclosure, even if the conditions of the protective resin to be loaded into the syringe have been changed over time, occurrence of a rise of the protective resin due to adhesion of a needless amount of the protective resin and occurrence of fading out of the protective resin due to application of the protective resin less than a required amount, at or proximate to the connection between the substrate and the film, are suppressed. This eliminates operations relying upon the operator's guesswork, such as ascertainment about the conditions of the protective resin to be loaded into the syringe and the determination of parameters for application operation based on the result of the ascertainment, and allows an amount of the protective resin to stably be applied uniformly from the start of application of the protective resin to the end of the application even if the conditions of the protective resin have been changed.

### BRIEF DESCRIPTION OF DRAWINGS

FIG. 1 is a plan view schematically showing the entirety of a display panel.

FIG. 2 is a plan view schematically showing a corner portion of the display panel.

FIG. 3 is a cross-sectional view schematically showing a connection between a film and a border portion (substrate).

FIG. 4 is a diagram showing mechanisms and functions of an application apparatus, together with a container storing a protective resin.

FIG. 5 is a flowchart illustrating a method for fabricating the display panel through application of protective resin.

FIG. 6 is a diagram showing a result of application experiment using a protective resin whose elapsed time is 144 hours or less.

FIG. 7 is a diagram showing a result of application experiment using a protective resin whose elapsed time is beyond 144 hours.

### DESCRIPTION OF EMBODIMENTS

A method for fabricating a display panel according to one aspect of the present disclosure is a method for fabricating a display panel in which a film which includes a conductor is connected to a border portion of a substrate having a rectangular shape, the border portion being between a periphery of the substrate and a periphery of a display area, the method including linearly applying a protective resin to a surface of the border portion onto which the film is connected, the protective resin protecting a connection between the substrate and the film, wherein linearly applying the protective resin includes: loading the protective resin having a viscosity of 4 Pa·s or greater and 6 Pa·s or less in an environment of 23 degrees Celsius into a syringe to which a nozzle is connected, the nozzle having a bore diameter 20% or greater and 30% or less of a width of the border portion; moving one of the substrate and the nozzle at a relative speed between the substrate and the nozzle of 26 mm/s or greater and 28 mm/s or less, if within 144 hours after a container containing the protective resin is first opened; moving one of the substrate and the nozzle at a relative speed between the substrate and the nozzle of 24 mm/s or greater and less than 26 mm/s, if beyond 144 hours after the container containing the protective resin is first opened; dispensing the protective resin pressurized by a gas having a pressure of 200 kPa or greater and 280 kPa or less from the nozzle, when a position of the nozzle relative to a position of the substrate is a first position; and stopping dispensing the protective resin when the position of the nozzle relative to the position of the substrate is a second position.

According to the above aspect, irrespective of an elapsed time since the container is opened, occurrence of a rise of the protective resin due to adhesion of a needless amount of the protective resin and occurrence of fading out of the protective resin due to application of the protective resin less than a required amount are suppressed. Thus, a uniform application state, such as a uniform amount of the protective resin applied from the start of application of the protective resin to the end of the application, is achieved, without relying upon the operator's guesswork, such as ascertainment about the conditions of the protective resin.

Next, an embodiment of a method for fabricating a display panel according to the present disclosure is described, with reference to the accompanying drawings. The embodiment described below is mere one example of the method according to the present disclosure. Thus, the scope of the present disclosure is limited by the terms of the appended claims, with reference to the embodiment below, and not limited to the embodiment below only. Therefore, among the components in the embodiment below, components not recited in any one of the independent claims indicating the most generic part of the inventive concept of the present disclosure are not necessary to achieve the present disclosure, but are described as components for preferable embodiments.

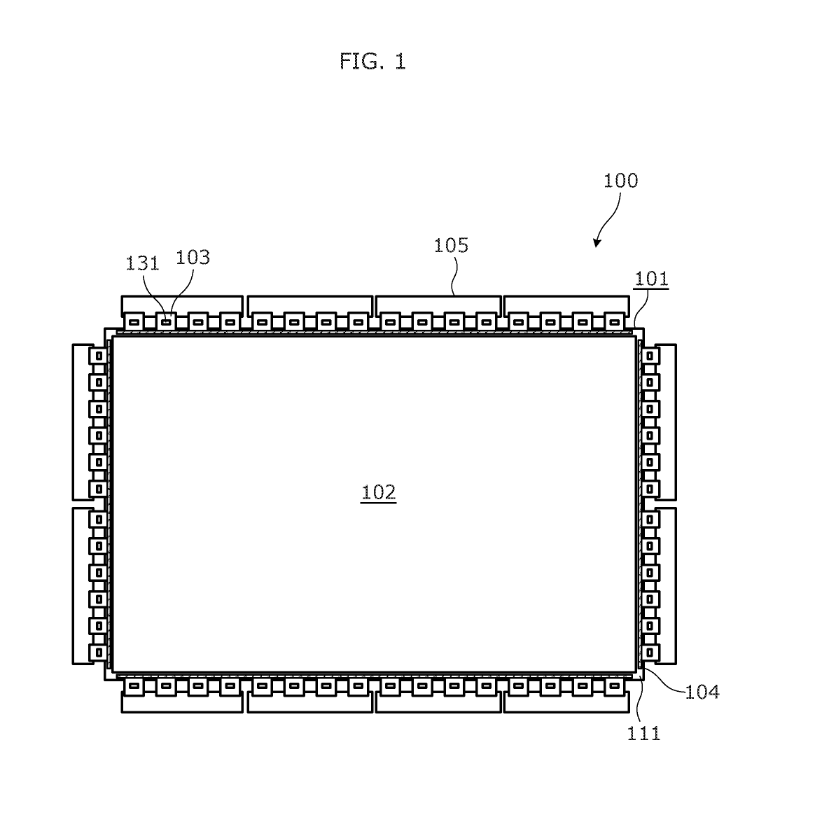

FIG. 1 is a plan view schematically showing the entirety of a display panel.

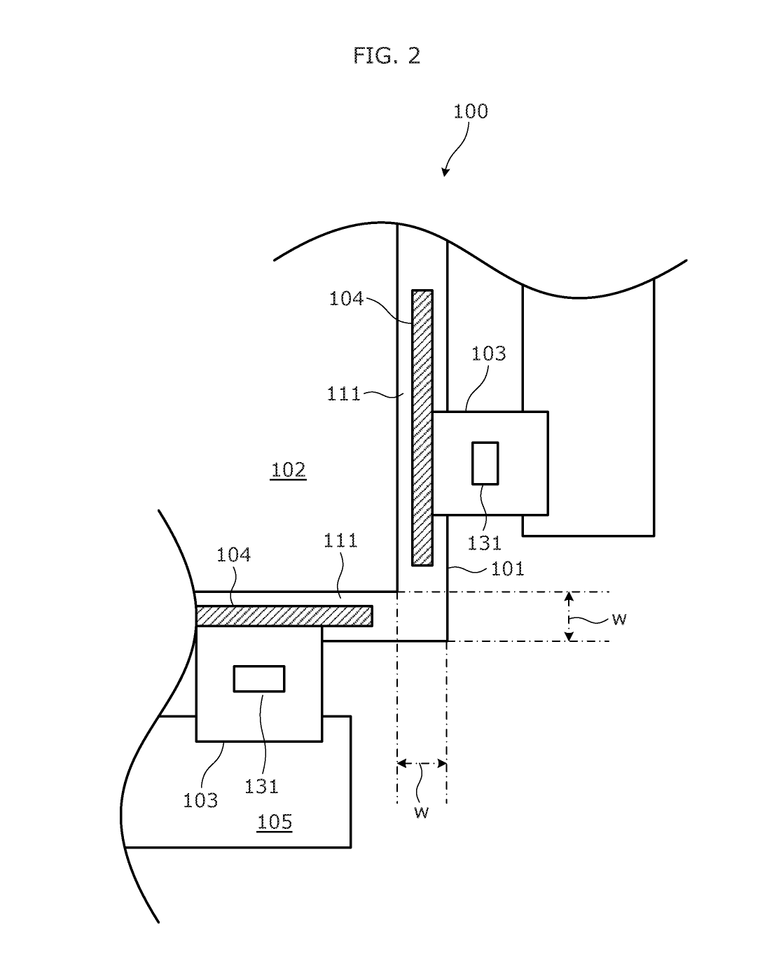

FIG. 2 is a plan view schematically showing a corner portion of the display panel.

As shown in the figures, a display panel 100 is an apparatus which displays characters and images (including videos) by controlling amounts of light emitted by (or amounts of light transmission through) tiny pixels (not shown) arranged in a matrix, based on an input signal. The display panel 100 includes a substrate 101, a display area 102 in which pixels are disposed, a plurality of films 103 which include conductors, and a protective resin 104. In the present embodiment, the display panel 100 further includes a circuit board 105 connected to the films 103.

The substrate 101 is a rectangular plate-shaped member which forms the structural basis for the display panel 100. The material of the substrate 101 is, but not particularly limited to, a transparent glass, for example.

The display area 102 has the pixels arranged in the matrix therein. The pixel as used herein, in the case where the display panel 100 is an organic EL display panel, for example, refers to a circuit which includes an organic EL element, a drive transistor, a selection transistor, a capacitor, etc.

The display area 102 also has a data line arranged for each column of pixels arranged in the matrix, and a scanning line arranged for each row of pixels. Moreover, a positive supply line and a negative supply line are arranged to be common to all the pixels.

These conductive lines are disposed extending to a border portion 111 external to the display area 102.

The border portion 111 is a portion of the substrate 101 between the periphery of the substrate 101 and the periphery of the display area 102. On the top surface of the border portion 111, a plurality of electrodes are disposed side by side, which are connected to the data lines, scanning lines, positive supply line, and negative supply line extending from the display area 102.

The film 103 is a so-called printed circuit film that has the conductive lines disposed on the top surface of a resin member by printing, and has pliability (flexibly) to be bent while maintaining the lines.

In the present embodiment, the film 103 is a so-called chip-on-film (COF) on which an electronic component 131 is mounted.

Examples of the electronic component 131 include, but not particularly limited to, an element which generates a drive voltage to be supplied to the pixels, based on a predetermined signal.

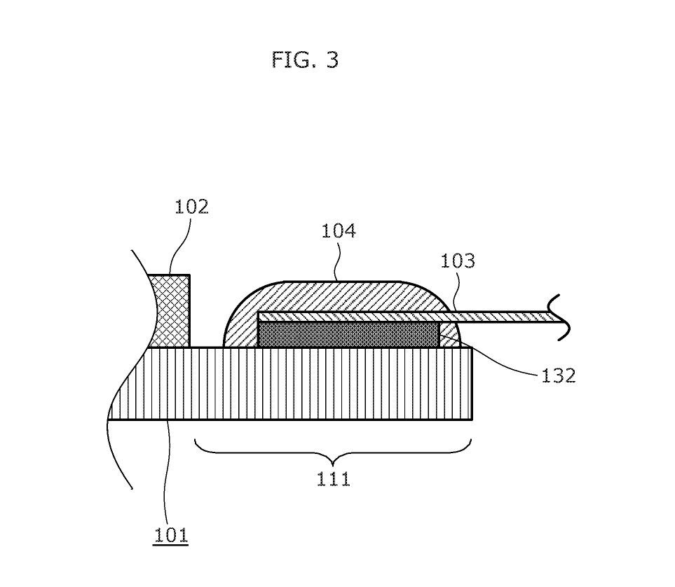

FIG. 3 is a cross-sectional view schematically showing the connection between the film 103 and the border portion 111 (substrate).

As shown in the figure, the film 103 is thermocompression bonded to the border portion 111 via an anisotropic conductive film 132 (ACF). The anisotropic conductive film 132 is a member which has properties that allow electrical connection between an electrode disposed on the border portion 111 and a line on the top surface of the film 103 above the electrode, when a force is applied to the anisotropic conductive film 132 in a direction in which the anisotropic conductive film 132 is placed between the film 103 and the substrate 101, while maintaining electrical isolation in a direction intersecting with the direction in which the anisotropic conductive film 132 is placed between the film 103 and the substrate 101. The anisotropic conductive film 132 not only provides the electrical communication but also mechanical connection between the film 103 and the substrate 101.

The protective resin 104 is a member applied onto the connection between the film 103 and the substrate 101 to provide hermeticity at the connection and protect and enhance the electrical and mechanical connections between the film 103 and the substrate 101 by the anisotropic conductive film 132. A method for fabricating the display panel through application of the protective resin 104 is described below.

The circuit board 105 is a component known as a printed circuit board. The circuit board 105 interfaces the electrical connection between a timing controller (T-CON) and the film 103, for example.

The timing controller as used herein refers to a logic circuit for controlling the timing of illumination of the pixels disposed in the display area 102 or amounts of emissions of light beams (amounts of light transmissions) of the pixels.

It should be noted that the circuit board 105 may be the timing controller.

Next, the method for fabricating the display panel through application of the protective resin 104 is described.

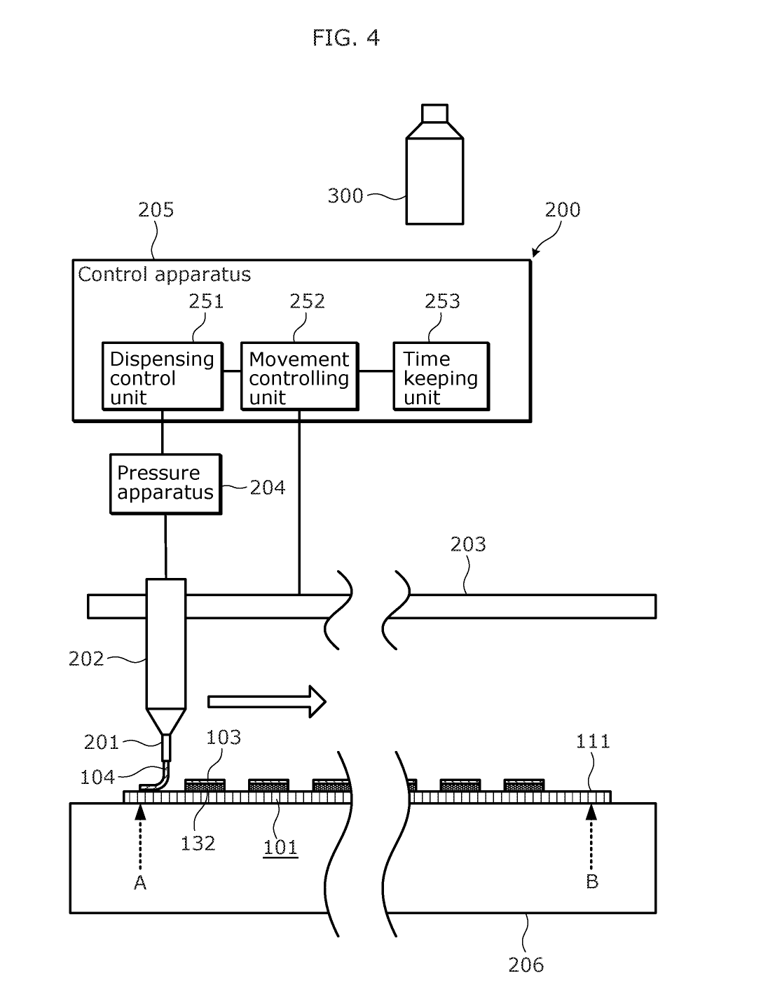

FIG. 4 is a diagram showing mechanisms and functions of an application apparatus, together with a resin storage container.

As shown in the figure, an application apparatus 200 is capable of applying the protective resin 104 linearly to the border portion 111 of the substrate 101 at the location to which the film 103 is connected, along one edge of the substrate 101. The application apparatus 200 includes a nozzle 201, a syringe 202, a moving apparatus 203, a pressure apparatus 204, a control apparatus 205, and a table 206.

The nozzle 201 is a tubular member for dispensing the protective resin 104 having a predetermined thickness. The nozzle 201 has a bore diameter 20% or greater and 30% or less of a width w (see FIG. 2) of the border portion 111. For example, if the border portion 111 has the width w of 2.5 mm, the nozzle 201 has a bore diameter selected from 0.5 mm or greater and 0.75 mm or less.

The syringe 202 includes, at the tip, the nozzle 201 in communication with the syringe 202. The syringe 202 is a container in which the protective resin 104 dispensed from the nozzle 201 is temporarily accumulated. The syringe 202 is such configured that a pressurized gas from the pressure apparatus 204 is supplied into the syringe 202.

The moving apparatus 203 is capable of moving the nozzle 201 relative to the substrate 101 at a constant speed. The moving apparatus 203 is configured to switch at least two speeds: a first speed which is a relative speed between the substrate 101 and the nozzle 201 selected from within 26 mm/s or greater and 28 mm/s or less; and a second speed which is a relative speed between the substrate 101 and the nozzle 201 selected from within 24 mm/s or greater and less than 26 mm/s. In the present embodiment, the moving apparatus 203 moves the nozzle 201 relative to the stationary substrate 101 in one direction, together with the syringe 202, that is, moves the nozzle 201 and the syringe 202 at 27 mm/s when the first speed is selected and at 25 mm/s when the second speed is selected.

The pressure apparatus 204 introduces a gas (an air) having a predetermined pressure into the syringe 202 to cause the nozzle 201 to dispense the protective resin 104 using the pressure of the gas. The pressure apparatus 204 is able to constantly supply a gas having a pressure selected from within 200 kPa or greater and 280 kPa or less.

The control apparatus 205 includes a dispensing control unit 251, a movement controlling unit 252, and a time keeping unit 253. The dispensing control unit 251 controls dispensing the protective resin 104. The movement controlling unit 252 controls the movement of the moving apparatus 203. The time keeping unit 253 keeps an elapsed time since a container 300 having the protective resin 104 accumulated therein is first opened. In the present embodiment, the control apparatus 205 is implemented by a computer, and the functionalities of the dispensing control unit 251, the movement controlling unit 252, and the time keeping unit 253 are implemented by executing software.

The table 206 is a member which holds the display panel 100. In the present embodiment, the table 206 is capable of rotating the display panel 100 in the vertical direction, and moving the display panel 100 in a horizontal plane for location adjustment.

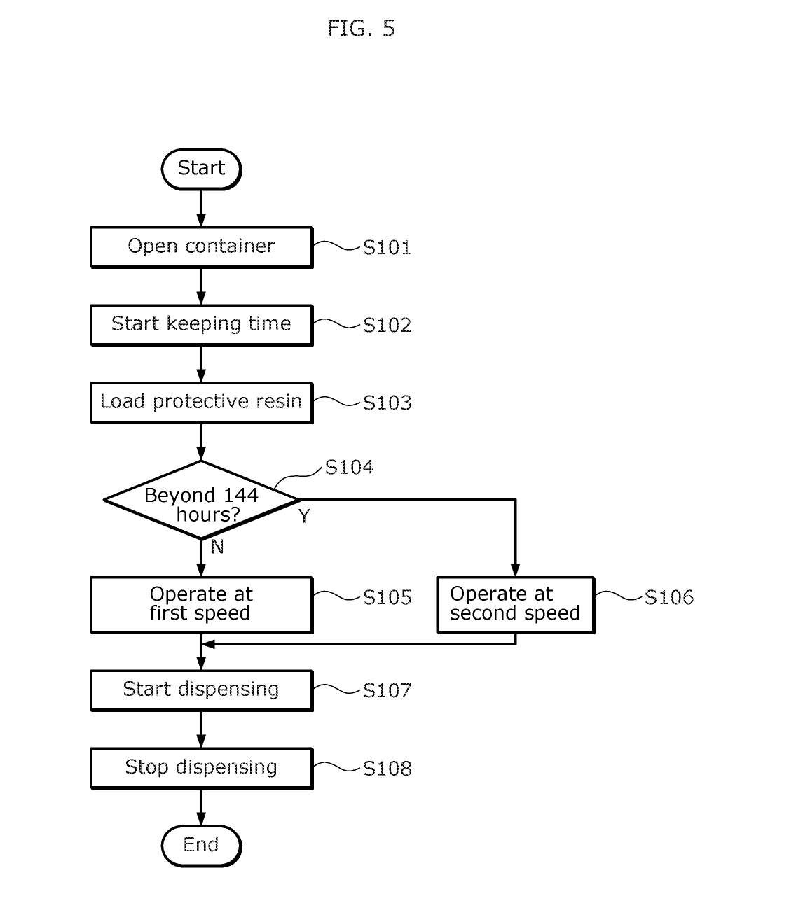

FIG. 5 is a flowchart illustrating the method for fabricating the display panel through application of the protective resin.

First, an operator opens the sealed container 300 in order to load the protective resin 104 into the syringe 202 (S101: opening process).

Next, the operator inputs to the control apparatus 205 information indicating that the container 300 has first been opened. Then, the time keeping unit 253 starts keeping time (S102: time keeping process). The information indicating that the container 300 has first been opened refers to information indicating a time at which the container 300 has been first opened, for example.

Next, the operator loads the protective resin 104 from the container 300 into the syringe 202 (S103: protective resin loading process). The protective resin 104 loaded herein is resin which has a viscosity of 4 Pa·s or greater and 6 Pa·s or less in an environment of 23 degrees Celsius. As a specific example, the protective resin 104 is a silicone containing material. As the protective resin 104 is applied, it extends to some extent due to the viscosity properties while reacting with moisture in the atmosphere, and is cured into a rubber-like elastic substance.

Next, the movement controlling unit 252 obtains from the time keeping unit 253 an elapsed time since the container 300 is first opened and determines whether the elapsed time is beyond 144 hours (5104: elapsed time determination process). If the elapsed time is 144 hours or less, the movement controlling unit 252 configures the moving apparatus 203 so that the relative speed between the substrate 101 and the nozzle 201 is the first speed (e.g., 27 mm/s), and causes the nozzle 201 to operate at the first speed (S105: first operating process). If the elapsed time is beyond 144 hours, on the other hand, the movement controlling unit 252 configures the moving apparatus 203 so that the relative speed between the substrate 101 and the nozzle 201 is the second speed (e.g., 25 mm/s), and causes the nozzle 201 to operate at the second speed (S106: second operating process).

Next, when the position of the nozzle 201 relative to the substrate 101 is a first position A (see FIG. 4), dispensing control unit 251 controls the pressure apparatus 204 to cause the protective resin 104 to be dispensed through the nozzle 201 by an air having a pressure of 200 kPa or greater and 280 kPa or less (e.g., 260 kPa) (S107: dispense start process).

Next, when the position of the nozzle 201 relative to the substrate 101 is a second position B (see FIG. 4), dispensing control unit 251 controls the pressure apparatus 204 to stop dispensing the protective resin 104 (S108: dispense stop process).

In the manner described above, the protective resin 104 is linearly applied to the border portion 111 of the substrate 101 along one side of the substrate 101. Applying the protective resin 104 according to the above conditions allows application of the protective resin 104 that has a uniform thickness, thereby inhibiting the applied protective resin 104 from rising or fading out partially (in particular, in the beginning and the end of the application).

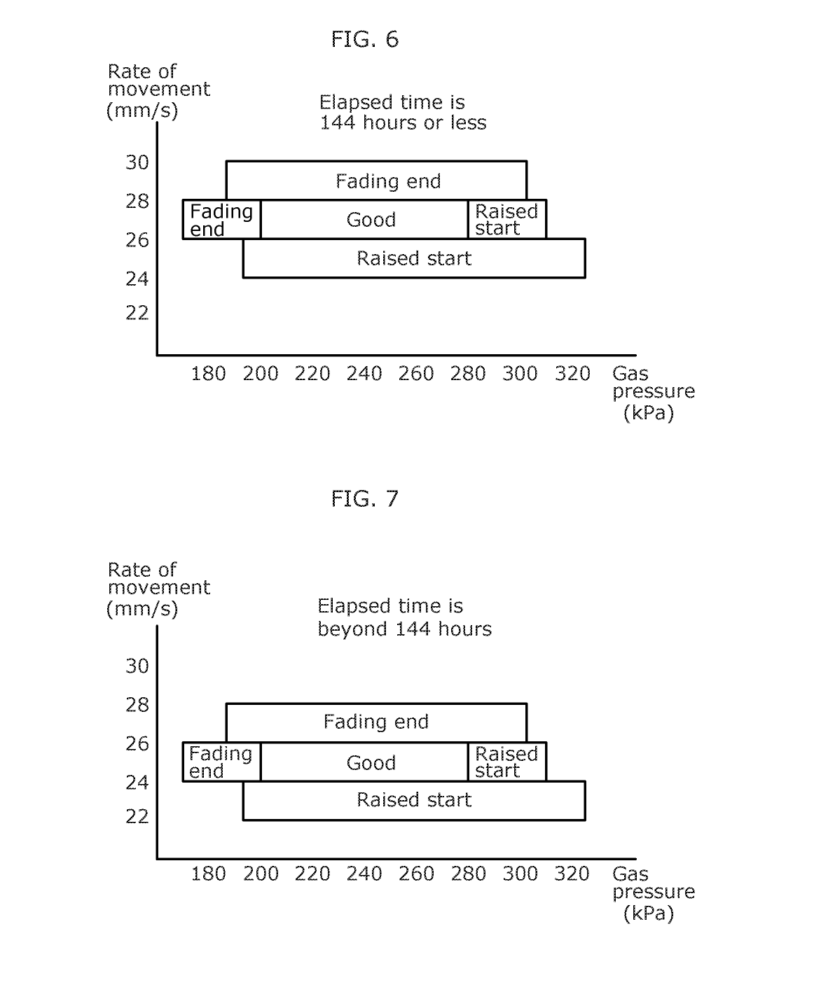

FIG. 6 is a diagram showing a result of application experiment using a protective resin whose elapsed time is 144 hours or less.

FIG. 7 is a diagram showing a result of application experiment using a protective resin whose elapsed time is beyond 144 hours.

The figures depict the results of application experiment in which the protective resins 104 were used whose elapsed time since the hermetically sealed containers 300 containing the protective resins 104 were first opened are different; the protective resins 104 were dispensed onto the substrate 101 in various combinations of different rates of movement and different gas pressures; and the application states of the protective resins 104 were confirmed by visual inspection.

As the results indicates, it was found that when a relatively new protective resin 104 whose elapsed time is 144 hours or less is dispensed by a gas having a pressure of 200 kPa or greater and 280 kPa or less, a good application state is obtained when the relative speed between the substrate 101 and the nozzle 201 is within 26 mm/s or greater and 28 mm/s or less, without occurrence of a raised start in which the protective resin 104 is needlessly applied immediately after the application starts and occurrence of fading end in which an amount of the protective resin 104 applied just before the application ends is not sufficient.

It was also found that when a relatively old protective resin 104 whose elapsed time is beyond 144 hours is dispensed, a failure occurs in the application state of the protective resin 104 under the above conditions, whereas a good application state is obtained when the relative speed between the substrate 101 and the nozzle 201 is within 24 mm/s or greater and less than 26 mm/s.

It should be noted that practice of a program for causing a computer to execute the processes included in the method for fabricating the display panel also corresponds to the practice of the present disclosure. Practice of a recording medium storing the program, of course, corresponds to the practice of the present disclosure as well.

The present disclosure is not limited the above embodiment. For example, the present disclosure encompasses embodiments implemented by any combination of the components shown herein and other embodiments implemented without some of the components in the above embodiment. Variations obtained by making various modifications to the above embodiment that may be conceived by a person skilled in the art are also included within the scope of the present disclosure, without departing from the spirit of the present disclosure, i.e., the terms of the appended claims.

For example, the operator may keep an elapsed time and set the relative time based on the elapsed time.

Alternatively, while the nozzle 201 is moved relative to the stationary substrate 101, the nozzle 201 may be made stationary and the substrate 101 may be moved. Alternatively, the nozzle 201 and the substrate 101 may be moved in opposite directions.

Alternatively, while the display panel 100 has been described, with reference to the films 103 connected to all the four sides of the border portion 111 of the substrate 101, the present disclosure is applicable to a display panel which includes the substrate 101 that has at least one side connected with the films 103.

### INDUSTRIAL APPLICABILITY

The present disclosure is applicable to methods for fabricating flat display apparatuses such as organic EL display apparatuses, liquid crystal display apparatuses, plasma display apparatuses, etc.

### REFERENCE SIGNS LIST

100 display panel
101 substrate
102 display area
103 film
104 protective resin
105 circuit board
111 border portion
131 electronic component
132 anisotropic conductive film
200 application apparatus
201 nozzle
202 syringe
203 moving apparatus
204 pressure apparatus
205 control apparatus
206 table
251 dispensing control unit
252 movement controlling unit
253 time keeping unit
300 container
A first position
B second position
w width

1. A method for fabricating a display panel in which a film which includes a conductor is connected to a border portion of a substrate having a rectangular shape, the border portion being between a periphery of the substrate and a periphery of a display area, the method comprising
linearly applying a protective resin to a surface of the border portion onto which the film is connected, the protective resin protecting a connection between the substrate and the film, wherein
linearly applying the protective resin includes:
loading the protective resin having a viscosity of 4 Pa·s or greater and 6 Pa·s or less in an environment of 23 degrees Celsius into a syringe to which a nozzle is connected, the nozzle having a bore diameter 20% or greater and 30% or less of a width of the border portion;
moving one of the substrate and the nozzle at a relative speed between the substrate and the nozzle of 26 mm/s or greater and 28 mm/s or less, if within 144 hours after a container containing the protective resin is first opened;
moving one of the substrate and the nozzle at a relative speed between the substrate and the nozzle of 24 mm/s or greater and less than 26 mm/s, if beyond 144 hours after the container containing the protective resin is first opened;
dispensing the protective resin pressurized by a gas having a pressure of 200 kPa or greater and 280 kPa or less from the nozzle, when a position of the nozzle relative to a position of the substrate is a first position; and
stopping dispensing the protective resin when the position of the nozzle relative to the position of the substrate is a second position.
